(19) United States
(12) Patent Application Publication
(10) Pub. No.: US 2024/0162074 A1
(43) Pub. Date: May 16, 2024

(54) Methods And Systems For Measurement Of Semiconductor Structures With Active Tilt Correction

(71) Applicant: KLA Corporation, Milpitas, CA (US)

(72) Inventors: Phalguna Rachinayani, San Jose, CA (US); Shankar Krishnan, Cupertino, CA (US); Elinore Esaghoulyan, Redwood City, CA (US)

(21) Appl. No.: 18/387,015

(22) Filed: Nov. 4, 2023

Related U.S. Application Data
(60) Provisional application No. 63/424,468, filed on Nov. 10, 2022.

(51) Int. Cl. H01L 21/68; H01L 21/66; H01L 21/67

(52) U.S. Cl. CPC H01L 21/681; H01L 21/67259; H01L 21/67288; H01L 22/24

(57) ABSTRACT

Wafer tilt is measured and compensated based on corrected measurements of tilt derived from a set of height measurements across a wafer. A set of wafer orientation correction values is generated by a measurement system at a large number of wafer locations. At each location, a wafer orientation correction value is determined based on a difference between the local wafer tilt of a calibration wafer measured by an optical tilt sensor and a corresponding estimated value of the local slope of the calibration wafer derived from Z-measurements. The same measurement system performs Z-measurements of a sample wafer and estimates the local slope at each location. The difference between the corresponding wafer orientation correction value and the local slope at each location accurately estimates the wafer orientation at each measurement location. The wafer orientation is adjusted based on the corrected value of wafer orientation.

### CROSS REFERENCE TO RELATED APPLICATION

The present application for patent claims priority under 35 U.S.C. § 119 from U.S. provisional patent application Ser. No. 63/424,468, entitled “Metrology and Inspection based on active tilt correction,” filed Nov. 10, 2022, the subject matter of which is incorporated herein by reference in its entirety.

### TECHNICAL FIELD

The described embodiments relate to metrology and inspection systems and methods, and more particularly to methods and systems with improved measurement accuracy.

### BACKGROUND INFORMATION

Semiconductor devices such as logic and memory devices are typically fabricated by a sequence of processing steps applied to a specimen. The various features and multiple structural levels of the semiconductor devices are formed by these processing steps. For example, lithography among others is one semiconductor fabrication process that involves generating a pattern on a semiconductor wafer. Additional examples of semiconductor fabrication processes include, but are not limited to, chemical-mechanical polishing, etch, deposition, and ion implantation. Multiple semiconductor devices may be fabricated on a single semiconductor wafer and then separated into individual semiconductor devices.

Metrology and inspection processes are used at various steps during a semiconductor manufacturing process to detect defects on wafers to promote higher yield. Available semiconductor measurement systems include film and critical dimension (CD) metrology, overlay metrology, bare wafer and product wafer inspection, etc. In many examples, X-Ray and optical metrology techniques offer the potential for high throughput without the risk of sample destruction. A number of X-ray and optical metrology based techniques including scatterometry, reflectometry, and ellipsometry implementations and associated analysis algorithms are commonly used to characterize critical dimensions, film thicknesses, composition, overlay and other parameters of nanoscale structures.

In general, wafers are positioned in the optical path of a metrology and inspection system during measurement. However, wafers and the positioning systems employed to locate the wafer are not perfectly flat. Thus, the orientation of the wafer surface at the measurement spot varies depending on the lateral position, i.e., x-y position, of the wafer with respect to the measurement system. This is a problem for several reasons. In some examples, metrology and inspection systems have a very thin focal plane, and variations in wafer tilt cause the measurement to fall out of focus. In some other examples, variations in wafer tilt introduce variations in the illumination angle of incidence. This introduces undesirable variation in measurement signals. A critical challenge faced in the development of many metrology and inspection systems is performing accurate measurements in the presence of local wafer tilt.

Local wafer tilt arises for various reasons. In one example, the wafer positioning stage employed to locate the wafer in the optical path of a measurement system is constructed with finite mechanical tolerances. Due to practical fabrication limitations, the wafer positioning stage itself does not maintain the wafer in the same orientation throughout its workspace, i.e., the orientation of an axis normal to a top surface of the wafer positioning stage depends on the lateral position of the stage. Similarly, the wafer chuck employed to fix the wafer to the wafer positioning stage is not perfectly flat. In another example, thickness variations across the wafer, the presence of backside particles, or both, give rise to flatness errors, and thus, the orientation of an axis normal to wafer surface under measurement varies depending on location on the wafer surface.

Local wafer tilt shifts the location of incidence of the illumination beam spot on the wafer. This leads to an induced shift in measurement results, e.g., measured spectra, that leads to measurement inaccuracy. In addition, since the local wafer tilt depends on individual tool characteristics, the induced local wafer tilt is different for each measurement tool. This increases tool-to-tool measurement variation, and limits achievable tool-to-tool matching.

In some examples, local wafer tilt is measured and corrected by adjusting system model calibration values. However, adjusting values of the system model does not physically change the location of incidence of the illumination beam spot at each measurement location on the wafer. Thus, this approach is unable to compensate for all of the induced errors. Achievable measurement accuracy and measurement sensitivity remains limited using existing measurement and calibration algorithms. In addition, determining the appropriate changes to system model calibration values is not always practical, or even possible, within reasonable constraints on computational effort and time to solution.

Future metrology and inspection applications present challenges due to increasingly small resolution requirements and the increasingly high value of wafer area. Thus, methods and systems for improved measurements in the presence of wafer tilt are desired.

### SUMMARY

Methods and systems for measurement and compensation of local wafer tilt based on corrected measurements of tilt derived from a set of height measurements across a wafer are described herein.

A set of wafer orientation correction values is generated at a large number of locations across a wafer surface, i.e., a wafer orientation correction map. At each location, a wafer orientation correction value is determined based on a difference between the local wafer tilt of a calibration wafer measured by an optical tilt sensor and a corresponding estimated value of the local slope of the calibration wafer derived from Z-measurements.

The optical tilt sensor accurately measures the actual local wafer tilt because the calibration wafer does not include thick films or patterned structures that introduce undesirable measurement errors. The estimated value of the local slope derived from the Z-measurements includes the actual local wafer tilt and also includes wafer tilt errors that arise from measured changes in wafer height. The difference value, i.e., the wafer orientation correction value, quantifies the wafer tilt errors present in the estimated value of the local slope derived from the Z-measurements.

When the same measurement system is employed to perform subsequent measurements on a sample wafer, the induced wafer tilt errors present in the estimated value of the local slope derived from the Z-measurements are the same as the wafer tilt errors captured by the wafer orientation correction value. When the wafer orientation correction value is subtracted from the local slope derived from the Z-measurements of the sample wafer, wafer orientation is accurately estimated at each measurement location.

In a further aspect, the corrected value of wafer orientation is communicated to a wafer stage. The wafer stage adjusts the orientation of the sample wafer based on the corrected value of wafer orientation to orient the surface of the wafer at the measurement spot at the desired in-plane orientation with respect to the measurement subsystem.

The foregoing is a summary and thus contains, by necessity, simplifications, generalizations and omissions of detail; consequently, those skilled in the art will appreciate that the summary is illustrative only and is not limiting in any way. Other aspects, inventive features, and advantages of the devices and/or processes described herein will become apparent in the non-limiting detailed description set forth herein.

### BRIEF DESCRIPTION OF THE DRAWINGS

FIG. 1 is a diagram illustrative of a system for measuring values of one or more parameters of interest characterizing a semiconductor structure after correcting wafer tilt errors in accordance with the exemplary methods presented herein.

FIG. 2 is another diagram illustrative of metrology system 100 depicted in FIG. 1.

FIG. 3 is a plot illustrative of the orientation of a prime grade bare silicon wafer about the Y_{W} axis depicted in FIG. 2 across the surface of the wafer.

FIG. 4 is a plot illustrative of the normal position of a prime grade bare silicon wafer along the Z_{W} axis measured at a number of selected locations across the wafer surface.

FIG. 5 is a plot illustrative of the computed local slope associated with each of the selected locations across the surface of the prime grade bare silicon wafer described with reference to FIG. 4.

FIG. 6 illustrates a method for estimating a desired correction of orientation of a semiconductor wafer based on corrected values of measured tilt as described herein.

### DETAILED DESCRIPTION

Reference will now be made in detail to background examples and some embodiments of the invention, examples of which are illustrated in the accompanying drawings.

Methods and systems for measurement and compensation of local wafer tilt based on corrected measurements of tilt derived from a set of height measurements across a wafer are described herein.

A large number of critical metrology and inspection applications involve measurements of wafers including thick film structures, patterned structures, e.g., critical dimension (CD) structures, or both. Unfortunately, direct measurement of local wafer tilt using an optical tilt sensor is prone to error when the wafer under measurement includes thick film structures, patterned structures, or both.

Accurate measurements of position of the semiconductor wafer with respect to the measurement subsystem in a direction normal to the surface of the semiconductor wafer, a.k.a., Z-measurements, are achievable using a variety of sensors, including Z-focus sensors currently integrated with many metrology and inspection tools. In some examples, Z-measurements adjacent to a measurement location are employed to estimate a local slope at the measurement location. Although the estimated local slope includes actual wafer tilt, local slope values derived from Z-measurements also include wafer tilt errors that arise from measured changes in wafer height, rather than actual wafer tilt. In one example, the changes in measured wafer height arise from movement of the wafer stage with respect to the measurement subsystem in the Z-direction as the wafer stage changes the location of measurement on the wafer surface, e.g., due to finite mechanical tolerances and alignment of the wafer stage components.

To address these limitations, a set of wafer orientation correction values is generated at a large number of locations across a wafer surface, i.e., a wafer orientation correction map. At each location, a wafer orientation correction value is determined based on a difference between the local wafer tilt of a calibration wafer measured by an optical tilt sensor and a corresponding estimated value of the local slope of the calibration wafer derived from Z-measurements. In preferred embodiments, the calibration wafer is a bare semiconductor wafer or a bare semiconductor wafer coated with a thin film having a thickness less than 5 nanometers.

The optical tilt sensor accurately measures the actual local wafer tilt because the calibration wafer does not include thick films or patterned structures that introduce undesirable measurement errors. The estimated value of the local slope derived from the Z-measurements includes the actual local wafer tilt and also includes wafer tilt errors that arise from measured changes in wafer height. The difference value, i.e., the wafer orientation correction value, quantifies the wafer tilt errors present in the estimated value of the local slope derived from the Z-measurements.

When the same measurement system is employed to perform subsequent measurements on a sample wafer, the induced wafer tilt errors present in the estimated value of the local slope derived from the Z-measurements are the same as the wafer tilt errors captured by the wafer orientation correction value. When the wafer orientation correction value is subtracted from the local slope derived from the Z-measurements of the sample wafer, wafer tilt is accurately estimated at each measurement location. In preferred embodiments, the sample wafer includes one or more thick film structures, one or more patterned structures, or both.

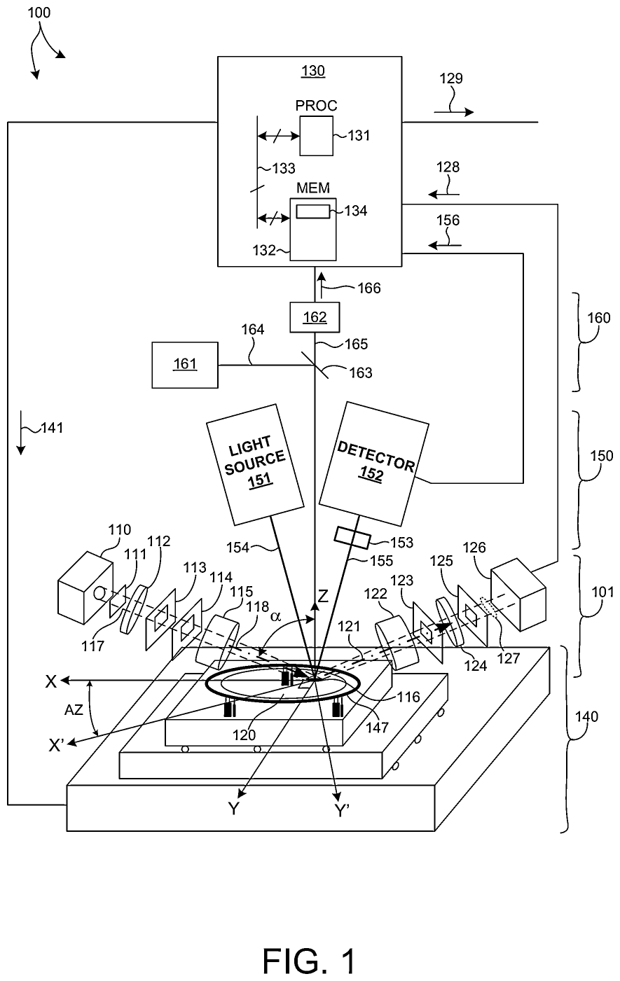

FIG. 1 depicts an exemplary, metrology system 100 for performing measurements of structural features of semiconductor devices. As depicted in FIG. 1, metrology system 100 is configured as a broadband spectroscopic ellipsometer. However, in general, metrology system 100 may be configured as a spectroscopic reflectometer, scatterometer, single wavelength ellipsometer, beam profile reflectometer, or any combination thereof.

Metrology system 100 includes an illumination source 110 that generates a beam of illumination light 117 incident on a wafer 120. In some embodiments, illumination source 110 is a broadband illumination source that emits illumination light in the ultraviolet, visible, and infrared spectra. In one embodiment, illumination source 110 is a laser sustained plasma (LSP) light source (a.k.a., laser driven plasma source). The pump laser of the LSP light source may be continuous wave or pulsed. A laser-driven plasma source can produce significantly more photons than a Xenon lamp across a wavelength range from 150 nanometers to 2000 nanometers. Illumination source 110 can be a single light source or a combination of a plurality of broadband or discrete wavelength light sources. The light generated by illumination source 110 includes a continuous spectrum or parts of a continuous spectrum, from ultraviolet to infrared (e.g., vacuum ultraviolet to mid infrared). In general, illumination light source 110 may include a super continuum laser source, an infrared helium-neon laser source, an arc lamp, or any other suitable light source.

In a further aspect, the amount of illumination light is broadband illumination light that includes a range of wavelengths spanning at least 500 nanometers. In one example, the broadband illumination light includes wavelengths below 250 nanometers and wavelengths above 750 nanometers. In general, the broadband illumination light includes wavelengths between 120 nanometers and 3,000 nanometers. In some embodiments, broadband illumination light including wavelengths beyond 3,000 nanometers may be employed.

As depicted in FIG. 1, metrology system 100 includes an illumination subsystem configured to direct illumination light 117 to one or more structures formed on the wafer 120 at an angle of incidence, a, defined with reference to an axis normal to the surface of wafer 120, e.g., the Z-axis depicted in FIG. 1. The illumination subsystem is shown to include light source 110, one or more optical filters 111, polarizing component 112, field stop 113, aperture stop 114, and illumination optics 115. The one or more optical filters 111 are used to control light level, spectral output, or both, from the illumination subsystem. In some examples, one or more multi-zone filters are employed as optical filters 111. Polarizing component 112 generates the desired polarization state exiting the illumination subsystem. In some embodiments, the polarizing component is a polarizer, a compensator, or both, and may include any suitable commercially available polarizing component. The polarizing component can be fixed, rotatable to different fixed positions, or continuously rotating. Although the illumination subsystem depicted in FIG. 1 includes one polarizing component, the illumination subsystem may include more than one polarizing component. Field stop 113 controls the field of view (FOV) of the illumination subsystem and may include any suitable commercially available field stop. Aperture stop 114 controls the numerical aperture (NA) of the illumination subsystem and may include any suitable commercially available aperture stop. Light from illumination source 110 is directed through illumination optics 115 to be focused on one or more structures (not shown in FIG. 1) on wafer 120. The illumination subsystem may include any type and arrangement of optical filter(s) 111, polarizing component 112, field stop 113, aperture stop 114, and illumination optics 115 known in the art of spectroscopic ellipsometry, reflectometry, and scatterometry.

As depicted, in FIG. 1, the beam of illumination light 117 passes through optical filter(s) 111, polarizing component 112, field stop 113, aperture stop 114, and illumination optics 115 as the beam propagates from the illumination source 110 to wafer 120. Beam 117 illuminates a portion of wafer 120 over a measurement spot 116.

Metrology system 100 also includes a collection optics subsystem configured to collect light generated by the interaction between the one or more structures and the incident illumination beam 117. A beam of collected light 127 is collected from measurement spot 116 by collection optics 122. Collected light 127 passes through collection aperture stop 123, polarizing element 124, and field stop 125 of the collection optics subsystem.

Collection optics 122 includes any suitable optical elements to collect light from the one or more structures formed on wafer 120. Collection aperture stop 123 controls the NA of the collection optics subsystem. Polarizing element 124 analyzes the desired polarization state. The polarizing element 124 is a polarizer or a compensator. The polarizing element 124 can be fixed, rotatable to different fixed positions, or continuously rotating. Although the collection subsystem depicted in FIG. 1 includes one polarizing element, the collection subsystem may include more than one polarizing element. Collection field stop 125 controls the field of view of the collection subsystem. The collection subsystem takes light from wafer 120 and directs the light through collection optics 122, and polarizing element 124 to be focused on collection field stop 125. In some embodiments, collection field stop 125 is used as a spectrometer slit for the spectrometers of the detection subsystem. In other embodiments, collection field stop 125 may be located at or near a spectrometer slit of the spectrometers of the detection subsystem.

The collection subsystem may include any type and arrangement of collection optics 122, aperture stop 123, polarizing element 124, and field stop 125 known in the art of spectroscopic ellipsometry, reflectometry, and scatterometry.

In the embodiment depicted in FIG. 1, the collection optics subsystem directs light to spectrometer 126. Spectrometer 126 generates output responsive to light collected from the one or more structures illuminated by the illumination subsystem. In one example, the detectors of spectrometer 126 are charge coupled devices (CCD) sensitive to ultraviolet and visible light (e.g., light having wavelengths between 190 nanometers and 860 nanometers). In other examples, one or more of the detectors of spectrometer 126 is a photo detector array (PDA) sensitive to infrared light (e.g., light having wavelengths between 950 nanometers and 2500 nanometers). However, in general, other detector technologies may be contemplated (e.g., a position sensitive detector (PSD), an infrared detector, a photovoltaic detector, etc.). Each detector converts the incident light into electrical signals indicative of the spectral intensity of the incident light. In general, spectrometer 126 generates output signals 128 indicative of the spectral response of the structure under measurement to the illumination light.

Metrology system 100 also includes computing system 130 configured to receive signals 128 indicative of the measured spectral response of the structure of interest and estimate values 129 of one or more parameters of interest characterizing the one or more structures under measurement, e.g., film thickness, critical dimensions, overlay, etc., based on the measured spectral response. Signals 128 indicative of the measured spectral response of the structure of interest are collected after the orientation of semiconductor wafer 120 is corrected by wafer stage 140 to minimize local wafer tilt at the measurement site as described herein.

Wafer stage 140 positions wafer 120 with respect to the ellipsometer subsystem 101. In some embodiments, wafer stage 140 moves wafer 120 in the XY plane by combining two orthogonal, translational movements (e.g., movements in the X and Y directions) to position wafer 120 with respect to the ellipsometer. In some embodiments, wafer stage 140 is configured to control the location of wafer 120 with respect to the illumination provided by the optical ellipsometer in six degrees of freedom. In one embodiment, wafer stage 140 is configured to control the azimuth angle, AZ, of wafer 120 with respect to the illumination provided by the optical ellipsometer by rotation about the z-axis. In general, specimen positioning system 140 may include any suitable combination of mechanical elements to achieve the desired linear and angular positioning performance, including, but not limited to goniometer stages, magnetically levitated stages, hexapod stages, angular stages, and linear stages. Computing system 130 is communicatively coupled to wafer stage 140 and communicates motion command signals 141 to wafer stage 140. In response, wafer stage 140 positions wafer 120 with respect to the ellipsometer in accordance with the motion control commands.

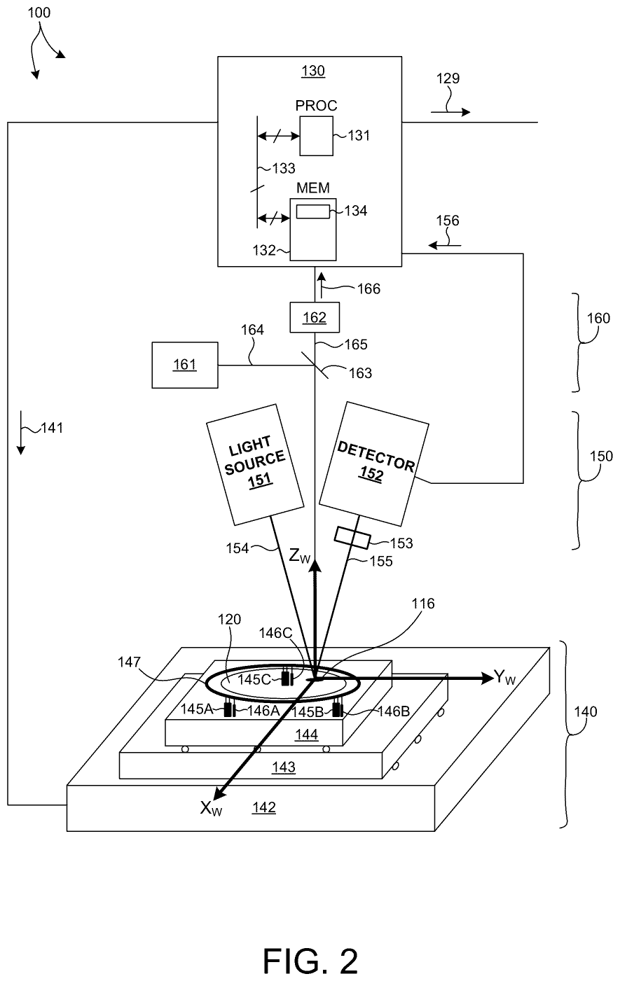

FIG. 2 is another diagram illustrative metrology system 100 depicted in FIG. 1. FIG. 2 does not include the elements of ellipsometer 101 to enable a more visible illustration of wafer stage 140.

As depicted in FIG. 2, wafer coordinate frame {X_{W}, Y_{W}, Z_{W}} is attached to wafer 120. The Z_{W} axis is normal to the surface of wafer 120 at measurement spot 116. The X_{W} and Y_{W} axes are orthogonal to one another and aligned with the surface of wafer 120. Wafer 120 is removably attached to wafer chuck 147, e.g., using a vacuum clamp, electrostatic clamp, edge grip clamp, etc.

As depicted in FIG. 2, wafer stage 140 includes a base frame 142, an X-stage 143, a Y-stage 144, and a three degree of freedom wafer stage supporting wafer chuck 147. In some embodiments, base frame 142 is mechanically coupled to a machine frame to which the measurement subsystem, e.g., ellipsometer 101, is also mechanically coupled. X-stage 143 is mechanically constrained by a bearing assembly, e.g., mechanical, magnetic, or air bearings, to move freely in X_{W} direction with respect to base frame 142. One or more actuators, e.g., linear motors, (not shown) are employed to control the position of X-stage 143 with respect to base frame 142 in the X_{W} direction. Similarly, Y-stage 144 is mechanically constrained by a bearing assembly, e.g., mechanical, magnetic, or air bearings, to move freely in Y_{W} direction with respect to X-stage 143. One or more actuators, e.g., linear motors, (not shown) are employed to control the position of Y-stage 144 with respect to X-stage 143 in the Y_{W} direction. As depicted in FIGS. 1 and 2, Y-stage 144 is stacked on X-stage 143. Together, X-stage 143 and Y-stage 144 provide a long stroke capability, i.e., workspace of at least 300 millimeters in the X_{W} and Y_{W} directions, such that X-stage 143 and Y-stage 144 are controlled to position any location on the surface of wafer 120 under measurement spot 116 defined by the optical elements of ellipsometer 101.

In the embodiment depicted in FIGS. 1 and 2, the three degree of freedom wafer stage includes actuators 145A-C, e.g., voice coil motors, piezoelectric motors, etc.). Each of actuators 145A-C is mechanically coupled between the wafer chuck 147 and Y-stage 144. The direction of extent of each of actuators 145A-C is approximately parallel to the Z_{W} axis, i.e., an axis normal to the surface of the wafer 120, which is clamped to wafer chuck 147. As depicted in FIGS. 1 and 2, actuators 145A-C are spaced apart from one another in the X_{W} and Y_{W} directions. In this configuration, the movements of actuators 145A-C are coordinated to independently control the position of wafer 120 in the Z-direction, the orientation of wafer 120 about the X_{W} axis, and the orientation of wafer 120 about the Y_{W} axis. Movements of wafer 120 specified in {Rₓ, Rₓ, Z} coordinates map to movements of actuators 145A-C by a simple kinematic transformation characterized by the geometric distances between actuators 145A-C and the {X_{W}, Y_{W}, Z_{W}} coordinate frame. In this manner, control commands 141 specifying movements in {Rₓ, Rₓ, Z} coordinates are readily mapped to movements of each actuator. The movements of each actuator are implemented at the actuator level by one or more motion controllers of wafer stage 140.

Similarly, position measurement devices 146A-C, e.g., linear encoders, linear variable differential transformers, inductive probes, capacitive probes, interferometers, etc.) are spaced apart from one another in the X_{W} and Y_{W} directions. In this configuration, the position of wafer 120 with respect to Y-stage 144 in the Z-direction, the orientation of wafer 120 about the X_{W} axis, and the orientation of wafer 120 about the Y_{W} axis are captured by position measurement devices 146A-C. The displacements captured by position measurement devices 146A-C map to displacements of wafer 120 expressed in the {Rₓ, R_{y}, Z} coordinates by a simple kinematic transformation characterized by the geometric distances between position measurement devices 146A-C and the {Rₓ, R_{y}, Z} coordinate frame. In this manner, displacements measured by position measurement devices 146A-C are readily mapped to displacements in {Rₓ, R_{y}, Z} coordinates. The displacements are communicated to computing system 130 for tilt correction as described herein. In some embodiments, the displacements are communicated to one or motion controllers of wafer stage 140 to implement a feedback positioning controller that locates wafer 120 at a desired position and orientation based on measurements by position measurement devices 146A-C.

In some embodiments, position measurement devices 146A-C are co-located with actuators 145A-C. Each of the position sensors is located in close proximity to a corresponding actuator, and thus measures a displacement in the direction of extent of each corresponding actuator. However, in general, position measurement devices 146A-C may be located in different locations than actuators 145A-C.

Wafer stage 140 illustrated in FIG. 2 includes a wafer stage having three actuators to generate force in the Z_{W}-direction at three different locations to control three degrees of freedom of wafer 120. However, in general, a wafer stage may include more than three actuators to generate force in the Z_{W} direction at more than three locations to control the three degrees of freedom of wafer 120. Although, such configurations are over-constrained, it may be desirable to include more than three actuators to limit the force requirements on any one actuator, stabilize bending modes in wafer chuck 147, operate in coordination as part of a magnetically levitated wafer chuck 147, etc.

Metrology system 100 also includes a wafer orientation measurement subsystem 150 coupled to the same machine frame as the measurement subsystem, e.g., ellipsometer 101. As depicted in FIGS. 1 and 2, wafer orientation measurement subsystem includes an optical illumination source 151 configured to generate an optical illumination beam 154 directed to the surface of wafer 120 at measurement spot 116. Light 155 reflected from the surface of wafer 120 in response to optical illumination beam 154 is focused by focusing optics 153 onto optical detector 152. Optical detector 152 generates signals 156 indicative of the orientation of wafer 120 with respect to the measurement subsystem, e.g., ellipsometer 101, at measurement spot 116 on the surface of wafer 120 based on a location of incidence of light 155 on optical detector 152. The measured orientation is the in-plane orientation of wafer 120, e.g., an orientation expressed in terms of angular position about the X_{W} and Y_{W} axes, which, by definition, lie within the same plane as the surface of the wafer. Rotational displacement about the Z_{W} axis is not captured by wafer orientation measurement subsystem 150.

By moving wafer 120 under wafer orientation measurement subsystem 150 such that measurement spot 116 is incident at selected locations across the surface of wafer 120, wafer orientation measurement subsystem 150 measures the in-plane orientation of wafer 120 at each location and generates a map of in-plane orientation measurements, e.g., orientation about in-plane axes, X_{W} and Y_{W}, corresponding to the selected locations.

In some embodiments, optical illumination source 151 is a Light Emitting Diode (LED) based light source. In other embodiments, optical illumination source 151 is a laser based light source. In some embodiments, optical illumination source is a Xenon arc-lamp based light source. In some of these embodiments, the optical illumination source is the same illumination source employed by the measurement subsystem, e.g., illumination source 110 of ellipsometer 101. In some embodiments, optical detector 152 is a quadrant cell photoreceiver. However, in general, any suitable optical illumination source and optical detector may be employed to measure the in-plane orientation of wafer 120 with respect to the measurement subsystem at measurement spot 116 on the surface of wafer 120.

As described hereinbefore, the measurement of in-plane orientation of wafer 120 using an optical detector, such as a quadrant cell photoreceiver is sensitive to structures fabricated on the surface of wafer 120, in particular high aspect ratio structures and thick films.

Metrology system 100 also includes a wafer normal position sensor subsystem 160 coupled to the same machine frame as the measurement subsystem, e.g., ellipsometer 101. As depicted in FIGS. 1 and 2, wafer normal position sensor subsystem 160 includes an optical illumination source 161 configured to generate an optical illumination beam 164 directed to the surface of wafer 120 at measurement spot 116 via optical element 163. Light 165 reflected from the surface of wafer 120 in response to optical illumination beam 164 is focused onto optical detector 162. Optical detector 162 generates signals 166 indicative of the normal position of wafer 120 with respect to the measurement subsystem, e.g., ellipsometer 101, at measurement spot 116 on the surface of wafer 120 based on a location of incidence of light 165 on optical detector 162. Each normal position value is a position of wafer 120 with respect to the measurement subsystem, e.g., ellipsometer 101, in a direction normal to the surface of wafer 120, i.e., along the Z_{W} axis.

By moving wafer 120 under wafer normal position sensor subsystem 160 such that measurement spot 116 is incident at selected locations across the surface of wafer 120, wafer normal position sensor subsystem 160 measures the normal position of wafer 120 at each location and generates a map of normal position measurements corresponding to the selected locations.

In some embodiments, the optical detector of a wafer normal position sensor subsystem is a bi-cell photoreceiver. In some embodiments, the optical detector of wafer normal position sensor subsystem 160 is a position sensitive detector comprising an array of photosensitive cells. In some embodiments, the optical detector of the wafer normal position sensor subsystem 160 is an interferometer. In some embodiments, the optical illumination source of a wafer normal position sensor subsystem, e.g., illumination source 161, is the same illumination source employed to provide illumination to a measurement subsystem, e.g., illumination source 110 of ellipsometer 101.

In some embodiments, a wafer normal position sensor subsystem is an element of an automatic focusing subsystem of a semiconductor measurement system, such as metrology system 100. The automatic focusing subsystem is configured to position the semiconductor wafer in a focal plane of the measurement subsystem, e.g., ellipsometer 101.

In some other embodiments, a wafer normal position sensor subsystem includes a linear encoder subsystem or grid encoder subsystem.

As described hereinbefore, the measurement of normal position of wafer 120 using an optical detector, such as a bi-cell photoreceiver, is insensitive to structures fabricated on the surface of wafer 120, in particular, high aspect ratio structures and thick films.

In one aspect, a measurement of wafer tilt at a measurement spot based on a local slope derived from adjacent Z-measurements is corrected by a wafer orientation correction map. The corrected measurement of wafer tilt accurately estimates the change of orientation of the wafer required to orient the surface of the wafer at the measurement spot at a desired in-plane orientation with respect to a measurement subsystem. In one example the measurement subsystem represented by an illumination source and detector of the measurement subsystem.

In a further aspect, a wafer orientation correction value at each wafer location is determined based on a difference between the orientation of a calibration wafer with respect to the measurement subsystem as measured by a wafer orientation measurement subsystem at each location and a corresponding estimated value of the local slope derived from Z-measurements at each location and adjacent locations.

In one example, wafer orientation measurement subsystem 150 is employed to measure the in-plane orientation of a calibration wafer with respect to ellipsometer 101 at selected locations on the surface of the calibration wafer to generate a map of in-plane orientation measurements corresponding to the selected locations.

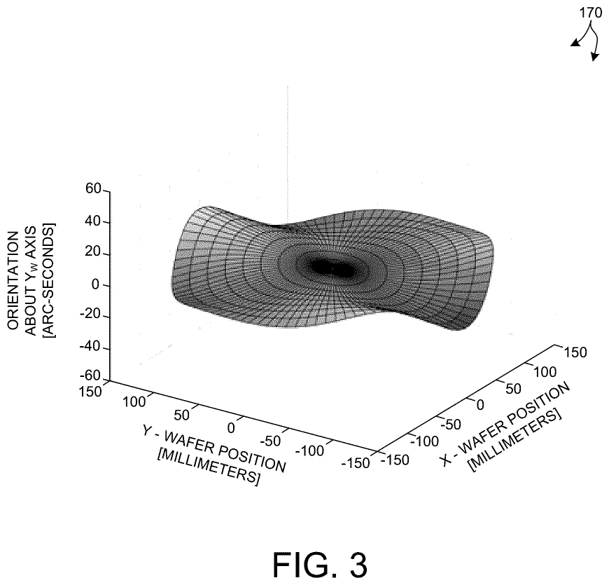

FIG. 3 is a plot 170 illustrative of the orientation of a prime grade bare silicon wafer about the Y_{W} axis depicted in FIG. 2 over the entire surface of the wafer. This corresponds to rotational displacements in and out of the plane of incidence of ellipsometer 101. As depicted in FIG. 3, the range of variation in orientation about the Y_{W} axis is 30 arc-seconds, or more. These variations are representative of the unflatness of the wafer stage and wafer chuck.

In a further aspect, wafer normal position sensor subsystem 160 is employed to measure the normal position of the calibration wafer with respect to ellipsometer 101 at the selected locations on the surface of the calibration wafer. In this manner, wafer normal position sensor subsystem 160 generates a map of normal position measurements corresponding to the selected locations.

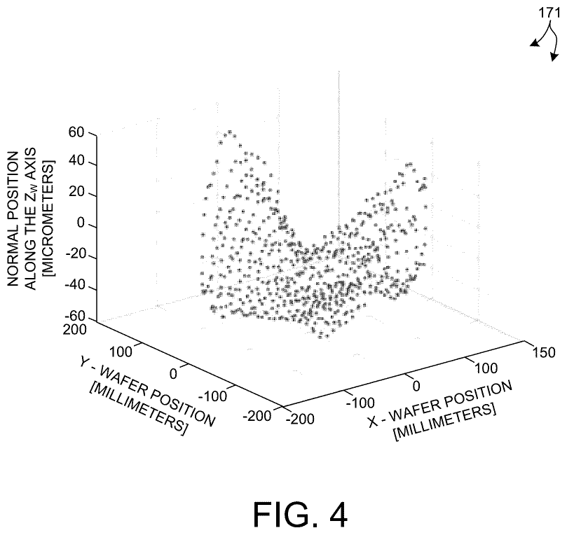

FIG. 4 is a plot 171 illustrative of the normal position of a prime grade bare silicon wafer along the Z_{W} axis measured at a large number of locations across the wafer surface. As depicted in FIG. 4, the range of variation in normal position along the Z_{W} axis is as much as 80 micrometers. These variations are representative of the unflatness of the wafer stage, wafer chuck, and wafer.

In a further aspect, values characterizing a local slope associated with each of the selected locations across the surface of the calibration semiconductor wafer are estimated based on the normal position values. More specifically, at each selected location a gradient value is computed in the X-direction and the Y-direction based on the normal position value at the selected location and the normal position values adjacent to the selected location. The gradient value expresses the change in normal position (along the Z-direction) divided by the change in lateral position (along the X and Y directions).

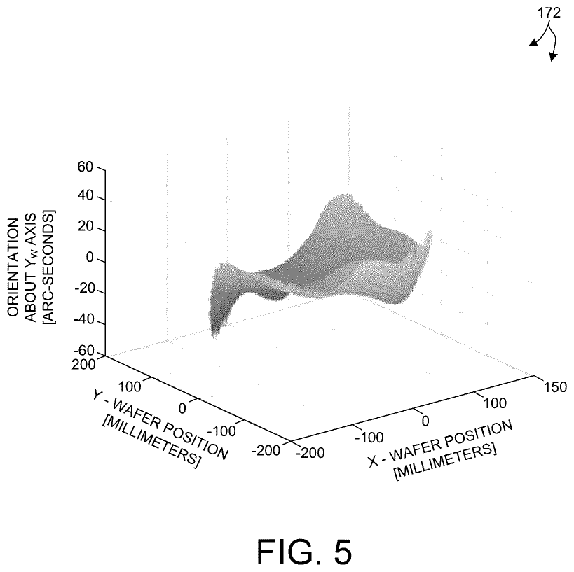

FIG. 5 is a plot 172 illustrative of the computed local slope associated with each of the selected locations across the surface of the prime grade bare silicon wafer described with reference to FIG. 4.

In a further aspect, a wafer orientation correction map is generated based on a difference between the estimated orientation of the calibration semiconductor wafer with respect to the measurement subsystem and the estimated values characterizing the local slope at each of the selected locations across the surface of the calibration semiconductor wafer.

At each selected location, the difference between the estimated orientation of the calibration semiconductor wafer as measured by the wafer orientation measurement subsystem 150 and the value of the local slope derived from the normal position measurements is computed. In this manner, a map of wafer orientation measurement subsystem 150 generates a map of wafer orientation correction values corresponding to the selected locations.

As illustrated by Equation (1), a set of wafer orientation correction values about the X_{W} and Y_{W} axes, {R_{XW}, R_{YW}}^{CORR}, is calculated as the difference between the local slope about the X_{W} and Y_{W} axes derived from Z-measurements of a calibration wafer, _{CAL}{R_{XW}, R_{YW}}^{Z}, and the orientation of the calibration wafer about the X_{W} and Y_{W} axes as measured by an optical tilt sensor, _{CAL}{R_{XW}, R_{YW}}^{TILT}.

{R_{XW},R_{YW}}^{CORR}=_{CAL}{R_{XW},R_{YW}}^{Z}−_{CAL}{R_{XW},R_{YW}}^{TILT} (1)

R_{XW} and R_{XY} are vectors of the same length. Each pair of wafer orientation correction values corresponds to a different selected location on the wafer. Thus, {R_{XW}, R_{YW}}^{CORR}, is a map of wafer orientation correction values corresponding to the selected locations.

In a further aspect, wafer normal position sensor subsystem 160 is employed to measure the normal position of a sample wafer with respect to ellipsometer 101 at selected locations on the surface of the sample wafer. In this manner, wafer normal position sensor subsystem 160 generates a map of normal position measurements corresponding to the selected locations.

In a further aspect, values characterizing a local slope associated with each of the selected locations across the surface of the sample semiconductor wafer are estimated based on the normal position values.

In a further aspect, for each selected location across the surface of the sample wafer, a corrected value of the wafer orientation is determined by subtracting the wafer orientation correction value corresponding to the selected location from the local slope computed at the selected location. In this manner, the induced measurement error due to height variation is removed from the local slope value computed at each selected location.

As illustrated by Equation (2), a set of corrected orientation values about the X_{W} and Y_{W} axes, ₛ{R^{XW}, R_{YW}}, associated with the sample wafer is calculated as the difference between the local slope about the X_{W} and Y_{W} axes derived from Z-measurements of the sample wafer, ₛ{R^{XW}, R_{YW}}^{Z}, and the wafer orientation correction value corresponding to each selected location on the wafer, ₛ{R^{XW}, R_{YW}}^{CORR}.

ₛ{R_{XW},R_{YW}}=ₛ{R_{XW},R_{YW}}^{Z}−{R_{XW},R_{YW}}^{CORR} (2)

If a wafer orientation correction value corresponds directly to the selected location, the wafer orientation correction value is used directly. However, if there is no wafer orientation correction value that corresponds directly to the selected location, interpolation among wafer orientation correction values corresponding to wafer locations adjacent to the selected location is employed to compute the wafer orientation correction value.

As depicted in FIGS. 1 and 2, wafer stage 140 is configured to position wafer 120 in multiple degrees of freedom including a rotational degree of freedom about the X_{W} axis and a rotational degree of freedom about the Y_{W} axis based on a desired correction of orientation to minimize wafer tilt at the measurement spot 116.

In a further aspect, the corrected value of wafer orientation is communicated to wafer stage 140, and wafer stage 140 adjusts the orientation of the sample wafer based on the corrected value of wafer orientation to orient the surface of the wafer at the measurement spot at the desired in-plane orientation with respect to the measurement subsystem.

In some embodiments, active correction of local tilt in a spectroscopic ellipsometer, single wavelength ellipsometer, or a beam profile reflectometer is achieved by manipulating the orientation of the wafer under measurement based on active measurement of local tilt. In some of these embodiments, the local tilt is measured and the wafer stage adjusts the orientation of the wafer such that the tilt about the X_{W} and Y_{W} axes is eliminated. In some other embodiments, the wafer stage adjusts the orientation of the wafer based on a local wafer orientation correction map. The local wafer orientation correction map specifies the desired change of the orientation of the wafer such that the tilt about the X_{W} and Y_{W} axes is eliminated based on the location of the measurement spot on the wafer. The wafer stage adjusts the orientation of the wafer in accordance with the value of local wafer orientation correction corresponding to the measurement location on the wafer.

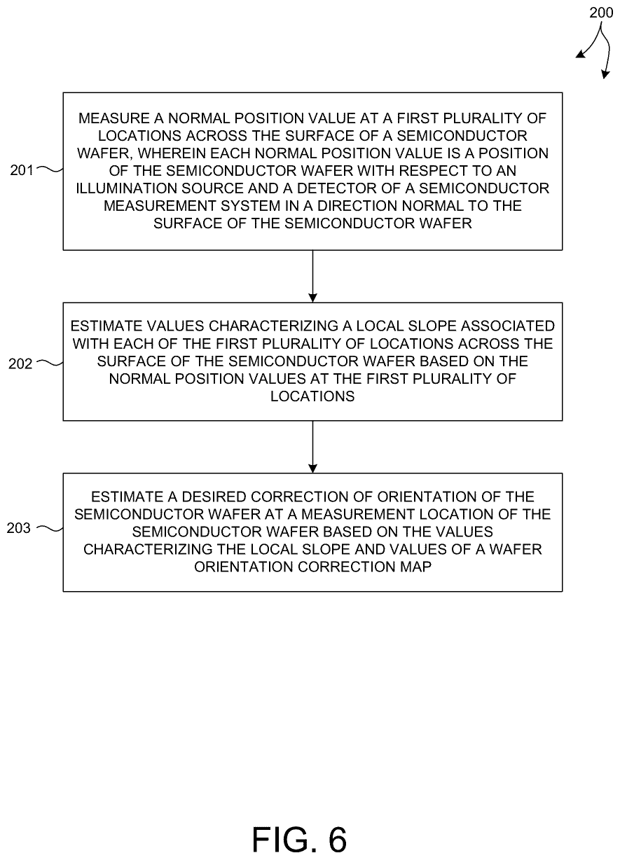

FIG. 6 illustrates a method 200 suitable for implementation by a metrology system such as metrology system 100 illustrated in FIGS. 1 and 2 of the present invention. In one aspect, it is recognized that data processing blocks of method 200 may be carried out via a pre-programmed algorithm executed by one or more processors of computing system 130, or any other general purpose computing system. It is recognized herein that the particular structural aspects of metrology system 100 do not represent limitations and should be interpreted as illustrative only.

In block 201, a normal position value at a first plurality of locations across the surface of a semiconductor wafer is measured. Each normal position value is a position of the semiconductor wafer with respect to an illumination source and a detector of a semiconductor measurement system in a direction normal to the surface of the semiconductor wafer.

In block 202, values characterizing a local slope associated with each of the first plurality of locations across the surface of the semiconductor wafer are estimated based on the normal position values at the first plurality of locations.

In block 203, a desired correction of orientation of the semiconductor wafer at a measurement location of the semiconductor wafer is estimated based on the values characterizing the local slope and values of a wafer orientation correction map.

Exemplary measurement techniques that may benefit from correction of wafer tilt as described herein include, but are not limited to, optical spectroscopic tools such as a Mueller ellipsometer, spectroscopic ellipsometer, single wavelength ellipsometer, spectroscopic reflectometer, beam profile reflectometer, an imaging reflectometer, an imaging spectroscopic reflectometer, a polarized spectroscopic imaging reflectometer, a scanning reflectometer system, a system with two or more reflectometers capable of parallel data acquisition, a system with two or more spectroscopic reflectometers capable of parallel data acquisition, a system with two or more polarized spectroscopic reflectometers capable of parallel data acquisition, a system with two or more polarized spectroscopic reflectometers capable of serial data acquisition without moving the wafer stage or moving any optical elements or the reflectometer stage, imaging spectrometers, imaging system with wavelength filter, imaging system with long-pass wavelength filter, imaging system with short-pass wavelength filter, imaging system without wavelength filter, interferometric imaging system, imaging ellipsometer, imaging spectroscopic ellipsometer, a scanning ellipsometer system, a system with two or more ellipsometers capable of parallel data acquisition, a system with two or more ellipsometers capable of serial data acquisition without moving the wafer stage or moving any optical elements or the ellipsometer stage, a Michelson interferometer, a Mach-Zehnder interferometer, a Sagnac interferometer, a scanning angle of incidence system, a scanning azimuth angle system, a wafer inspection system, an x-ray based metrology system, and electron beam metrology tool, etc. Furthermore, in general, measurement data collected by different measurement technologies and analyzed in accordance with the methods described herein may be collected from multiple tools, rather than one tool integrating multiple technologies.

In a further embodiment, system 100 may include one or more computing systems 130 employed to perform measurements in accordance with the methods described herein. The one or more computing systems 130 may be communicatively coupled to the detectors 126, 152, and 162. In one aspect, the one or more computing systems 130 are configured to receive measurement data 128 associated with measurements of metrology targets disposed on specimen 120.

It should be recognized that the various steps described throughout the present disclosure may be carried out by a single computer system 130 or, alternatively, a multiple computer system 130. Moreover, different subsystems of the system 100, such as detectors 126, 152, and 162, wafer stage 140, etc., may include a computer system suitable for carrying out at least a portion of the steps described herein. Therefore, the aforementioned description should not be interpreted as a limitation on the present invention but merely an illustration. Further, the one or more computing systems 130 may be configured to perform any other step(s) of any of the method embodiments described herein.

In addition, the computer system 130 may be communicatively coupled to detectors 126, 152, and 162 in any manner known in the art. For example, the one or more computing systems 130 may be coupled to computing systems associated with detectors 126, 152, and 162. In another example, detectors 126, 152, and 162 may be controlled directly by a single computer system coupled to computer system 130.

The computer system 130 of metrology system 100 may be configured to receive and/or acquire data or information from the subsystems of the system (e.g., detectors 126, 152, and 162 and the like) by a transmission medium that may include wireline and/or wireless portions. In this manner, the transmission medium may serve as a data link between the computer system 130 and other subsystems of the system 100.

Computer system 130 of metrology system 100 may be configured to receive and/or acquire data or information (e.g., measurement results, modeling inputs, modeling results, etc.) from other systems by a transmission medium that may include wireline and/or wireless portions. In this manner, the transmission medium may serve as a data link between the computer system 130 and other systems (e.g., memory on-board metrology system 100, external memory, a reference measurement source, or other external systems). For example, the computing system 130 may be configured to receive measurement data from a storage medium (i.e., memory 132 or an external memory) via a data link. For instance, measurement results obtained using detectors 126, 152, and 162 may be stored in a permanent or semi-permanent memory device (e.g., memory 132 or an external memory). In this regard, the measurement results may be imported from on-board memory or from an external memory system. Moreover, the computer system 130 may send data to other systems via a transmission medium. For instance, a measurement model or estimated values of one or more parameters of interest 129 determined by computer system 130 may be communicated and stored in an external memory. In this regard, measurement results may be exported to another system.

Computing system 130 may include, but is not limited to, a personal computer system, cloud-based computer system, mainframe computer system, workstation, image computer, parallel processor, or any other device known in the art. In general, the term “computing system” may be broadly defined to encompass any device having one or more processors, which execute instructions from a memory medium.

Program instructions 134 implementing methods such as those described herein may be transmitted over a transmission medium such as a wire, cable, or wireless transmission link. For example, as illustrated in FIGS. 1 and 2, program instructions 134 stored in memory 132 are transmitted to processor 131 over bus 133. Program instructions 134 are stored in a computer readable medium (e.g., memory 132). Exemplary computer-readable media include read-only memory, a random access memory, a magnetic or optical disk, or a magnetic tape.

In another further aspect, the metrology system employed to perform measurements as described herein (e.g., metrology system 100) includes an infrared optical measurement system. In these embodiments, the metrology system 100 includes an infrared light source (e.g., an arc lamp, an electrode-less lamp, a laser sustained plasma (LSP) source, or a supercontinuum source). An infrared supercontinuum laser source is preferred over a traditional lamp source because of the higher achievable power and brightness in the infrared region of the light spectrum. In some examples, the power provided by the supercontinuum laser enables measurements of overlay structures with opaque film layers.

A potential problem in overlay measurement is insufficient light penetration to the bottom grating. In many examples, there are non-transparent (i.e., opaque) film layers between the top and the bottom gratings. Examples of such opaque film layers include amorphous carbon, tungsten silicide (WSIₓ), tungsten, titanium nitride, amorphous silicon, and other metal and non-metal layers. Often, illumination light limited to wavelengths in the visible range and below (e.g., between 250 nm and 700 nm) does not penetrate to the bottom grating. However, illumination light in the infrared spectrum and above (e.g., greater than 700 nm) often penetrates opaque layers more effectively.

In yet another aspect, the measurement results described herein can be used to provide active feedback to a process tool (e.g., lithography tool, etch tool, deposition tool, etc.). For example, values of film thickness, critical dimensions, overlay, etc., determined using the methods described herein can be communicated to a lithography tool to adjust the lithography system to achieve a desired output. In a similar way etch parameters (e.g., etch time, diffusivity, etc.) or deposition parameters (e.g., time, concentration, etc.) may be included in a measurement to provide active feedback to etch tools or deposition tools, respectively.

In general, the systems and methods described herein can be implemented as part of the process of off-line or on-tool measurement.

As described herein, the term “critical dimension” includes any critical dimension of a structure (e.g., bottom critical dimension, middle critical dimension, top critical dimension, sidewall angle, grating height, etc.), a critical dimension between any two or more structures (e.g., distance between two structures), and a displacement between two or more structures (e.g., overlay displacement between overlaying grating structures, etc.). Structures may include three dimensional structures, patterned structures, overlay structures, etc.

As described herein, the term “critical dimension application” or “critical dimension measurement application” includes any critical dimension measurement.

As described herein, the term “metrology system” includes any system employed at least in part to characterize a specimen in any aspect, including measurement applications such as critical dimension metrology, overlay metrology, focus/dosage metrology, and composition metrology. However, such terms of art do not limit the scope of the term “metrology system” as described herein. In addition, the metrology system 100 may be configured for measurement of patterned wafers and/or unpatterned wafers. The metrology system may be configured as a LED inspection tool, edge inspection tool, backside inspection tool, macro-inspection tool, or multi-mode inspection tool (involving data from one or more platforms simultaneously), and any other metrology or inspection tool that benefits from the correction of wafer tilt.

Various embodiments are described herein for a semiconductor processing system (e.g., an inspection system or a lithography system) that may be used for processing a specimen. The term “specimen” is used herein to refer to a wafer, a reticle, or any other sample that may be processed (e.g., printed or inspected for defects) by means known in the art.

As used herein, the term “wafer” generally refers to substrates formed of a semiconductor or non-semiconductor material. Examples include, but are not limited to, monocrystalline silicon, gallium arsenide, and indium phosphide. Such substrates may be commonly found and/or processed in semiconductor fabrication facilities. In some cases, a wafer may include only the substrate (i.e., bare wafer). Alternatively, a wafer may include one or more layers of different materials formed upon a substrate. One or more layers formed on a wafer may be “patterned” or “unpatterned.” For example, a wafer may include a plurality of dies having repeatable pattern features.

A “reticle” may be a reticle at any stage of a reticle fabrication process, or a completed reticle that may or may not be released for use in a semiconductor fabrication facility. A reticle, or a “mask,” is generally defined as a substantially transparent substrate having substantially opaque regions formed thereon and configured in a pattern. The substrate may include, for example, a glass material such as amorphous SiO₂. A reticle may be disposed above a resist-covered wafer during an exposure step of a lithography process such that the pattern on the reticle may be transferred to the resist.

One or more layers formed on a wafer may be patterned or unpatterned. For example, a wafer may include a plurality of dies, each having repeatable pattern features. Formation and processing of such layers of material may ultimately result in completed devices. Many different types of devices may be formed on a wafer, and the term wafer as used herein is intended to encompass a wafer on which any type of device known in the art is being fabricated.

In one or more exemplary embodiments, the functions described may be implemented in hardware, software, firmware, or any combination thereof. If implemented in software, the functions may be stored on or transmitted over as one or more instructions or code on a computer-readable medium. Computer-readable media includes both computer storage media and communication media including any medium that facilitates transfer of a computer program from one place to another. A storage media may be any available media that can be accessed by a general purpose or special purpose computer. By way of example, and not limitation, such computer-readable media can comprise RAM, ROM, EEPROM, CD-ROM or other optical disk storage, magnetic disk storage or other magnetic storage devices, or any other medium that can be used to carry or store desired program code means in the form of instructions or data structures and that can be accessed by a general-purpose or special-purpose computer, or a general-purpose or special-purpose processor. Also, any connection is properly termed a computer-readable medium. For example, if the software is transmitted from a website, server, or other remote source using a coaxial cable, fiber optic cable, twisted pair, digital subscriber line (DSL), or wireless technologies such as infrared, radio, and microwave, then the coaxial cable, fiber optic cable, twisted pair, DSL, or wireless technologies such as infrared, radio, and microwave are included in the definition of medium. Disk and disc, as used herein, includes compact disc (CD), laser disc, optical disc, digital versatile disc (DVD), floppy disk and blu-ray disc where disks usually reproduce data magnetically, while discs reproduce data optically with lasers. Combinations of the above should also be included within the scope of computer-readable media.

Although certain specific embodiments are described above for instructional purposes, the teachings of this patent document have general applicability and are not limited to the specific embodiments described above. Accordingly, various modifications, adaptations, and combinations of various features of the described embodiments can be practiced without departing from the scope of the invention as set forth in the claims.

What is claimed is:

1. A semiconductor measurement system comprising:
an illumination source configured to generate an amount of illumination radiation incident on a semiconductor wafer, wherein one or more structures are fabricated on a surface of the semiconductor wafer;
a detector configured to detect an amount of collected radiation from the semiconductor wafer in response to the incident amount of illumination radiation;
a wafer normal position sensor subsystem configured to measure a normal position value at a first plurality of locations across the surface of the semiconductor wafer, wherein each normal position value is a position of the semiconductor wafer with respect to the illumination source and the detector in a direction normal to the surface of the semiconductor wafer;
a computing system configured to:
estimate values characterizing a local slope associated with each of the first plurality of locations across the surface of the semiconductor wafer based on the normal position values at the first plurality of locations; and
estimate a desired correction of orientation of the semiconductor wafer at a measurement location of the semiconductor wafer based on the values characterizing the local slope and values of a wafer orientation correction map.

2. The semiconductor measurement system of claim 1, further comprising:
a specimen positioning system configured to orient the semiconductor wafer about a first axis and a second axis at the measurement location based on the desired correction of orientation, wherein the first and second axes are aligned with the surface of the semiconductor wafer and the second axis is orthogonal to the first axis.

3. The semiconductor measurement system of claim 2, the computing system further configured to:
estimate a value of a parameter of interest characterizing the one or more structures based on an amount of collected radiation detected at the measurement spot after the semiconductor wafer is oriented about the first and second axes based on the desired correction of orientation.

4. The semiconductor measurement system of claim 1, further comprising:
a wafer orientation measurement subsystem comprising:
a first optical illumination source configured to generate an optical illumination beam directed to a surface of a calibration semiconductor wafer; and
a first optical detector configured to detect light reflected from the calibration semiconductor wafer in response to the incident optical illumination beam, wherein the computing system is further configured to:
estimate an orientation of the calibration semiconductor wafer with respect to the illumination source and the detector at each of a second plurality of locations across the surface of the calibration semiconductor wafer based on a location of incidence of the light reflected from the calibration semiconductor wafer on the first optical detector at each of the second plurality of locations across the surface of the calibration semiconductor wafer.

5. The semiconductor measurement system of claim 4,
wherein the wafer normal position sensor subsystem is further configured measure a normal position value at the second plurality of locations across the surface of the calibration semiconductor wafer, wherein each normal position value is a position of the unpatterned semiconductor wafer with respect to the illumination source and the detector in a direction normal to the surface of the calibration semiconductor wafer, and
wherein the computing system is further configured to:
estimate values characterizing a local slope associated with each of the second plurality of locations across the surface of the calibration semiconductor wafer based on the normal position values at the second plurality of locations; and
generate the wafer orientation correction map based on a difference between the estimated values characterizing the local slope at each of the second plurality of locations across the surface of the calibration semiconductor wafer and the estimated orientation of the calibration semiconductor wafer with respect to the illumination source and the detector.

6. The semiconductor measurement system of claim 1, wherein the wafer normal position sensor subsystem is an element of an automatic focusing subsystem of the semiconductor measurement system configured to position the semiconductor wafer in a focal plane of the illumination source and detector.

7. The semiconductor measurement system of claim 1, wherein the illumination source and the detector are elements of any of a single wavelength ellipsometer, a spectroscopic ellipsometer, a beam profile reflectometer, an x-ray based scatterometer, and a spectroscopic reflectometer.

8. The semiconductor measurement system of claim 1, wherein the one or more structures fabricated on the surface of the semiconductor wafer include one or more film structures, one or more critical dimension structures, or a combination thereof.

9. The semiconductor measurement system of claim 4, wherein the optical illumination source is a Light Emitting Diode (LED) based light source, a laser based light source, or a Xenon based light source.

10. The semiconductor measurement system of claim 4, wherein the optical detector is a quadrant cell photoreceiver.

11. The semiconductor measurement system of claim 1, the wafer normal position sensor subsystem, comprising:
an optical illumination source configured to generate an amount of optical illumination directed to the surface of the semiconductor wafer; and
an optical detector configured to detect light reflected from the semiconductor wafer in response to the incident optical illumination, wherein the computing system is further configured to estimate the normal position value at the first plurality of locations across the surface of the semiconductor wafer based on a location of incidence of the light reflected from the semiconductor wafer on the optical detector at each of the first plurality of locations across the surface of the semiconductor wafer.

12. The semiconductor measurement system of claim 11, wherein the optical detector is a bi-cell photoreceiver, a position sensitive detector comprising an array of photosensitive cells, or an interferometer.

13. The semiconductor measurement system of claim 11, wherein the illumination source and the optical illumination source are the same illumination source.

14. The semiconductor measurement system of claim 2, the specimen positioning system, comprising:
a two axis wafer stage configured to locate the semiconductor wafer with respect to the illumination source and the detector at any location on the surface of the semiconductor wafer;
a wafer chuck configured to removably couple the semiconductor wafer to the specimen positioning system; and
at least three actuators spaced apart from one another, wherein each of the at least three actuators is mechanically coupled between the wafer chuck and the two axis wafer stage, wherein a direction of extent of each of the at least three actuators is approximately parallel to a direction normal to the surface of the semiconductor wafer when coupled to the wafer chuck.

15. The semiconductor measurement system of claim 14, the specimen positioning system further comprising:
at least three position sensors, each of the at least three position sensors located in close proximity to a corresponding actuator of the at least three actuators, wherein each of the at least three position sensors is configured to measure a displacement in the direction of extent of each corresponding actuator.

16. A method comprising:
measuring a normal position value at a first plurality of locations across the surface of a semiconductor wafer, wherein each normal position value is a position of the semiconductor wafer with respect to an illumination source and a detector of a semiconductor measurement system in a direction normal to the surface of the semiconductor wafer;
estimating values characterizing a local slope associated with each of the first plurality of locations across the surface of the semiconductor wafer based on the normal position values at the first plurality of locations; and
estimating a desired correction of orientation of the semiconductor wafer at a measurement location of the semiconductor wafer based on the values characterizing the local slope and values of a wafer orientation correction map.

17. The method of claim 16, further comprising:
orienting the semiconductor wafer at the measurement location about a first axis and a second axis based on the desired correction of orientation, wherein the first and second axes are aligned with the surface of the semiconductor wafer and the second axis is orthogonal to the first axis.

18. The method of claim 17, further comprising:
generating an amount of illumination radiation incident on the semiconductor wafer at the measurement location, wherein one or more structures are fabricated on the surface of the semiconductor wafer;
detecting an amount of collected radiation from the semiconductor wafer in response to the incident amount of illumination radiation; and
estimating a value of a parameter of interest characterizing the one or more structures based on the amount of collected radiation detected at the measurement spot after the semiconductor wafer is oriented about the first and second axes based on the desired correction of orientation.

19. The method of claim 16, further comprising:
measuring a normal position value at a second plurality of locations across a surface of a calibration semiconductor wafer, wherein each normal position value is a position of the semiconductor wafer with respect to the illumination source and the detector of the semiconductor measurement system in a direction normal to the surface of the calibration semiconductor wafer;
estimating values characterizing a local slope associated with each of the second plurality of locations across the surface of the calibration semiconductor wafer based on the normal position values at the second plurality of locations; and
generating the wafer orientation correction map based on a difference between the estimated values characterizing the local slope at each of the second plurality of locations across the surface of the calibration semiconductor wafer and a measured orientation of the calibration semiconductor wafer with respect to the illumination source and the detector.

20. The method of claim 19, further comprising:
generating an optical illumination beam directed to the surface of the calibration semiconductor wafer;
detecting light reflected from the calibration semiconductor wafer in response to the incident optical illumination beam; and
determining the measured orientation of the calibration semiconductor wafer with respect to the illumination source and the detector at each of a second plurality of locations across the surface of the calibration semiconductor wafer based on a location of incidence of the detected light reflected from the calibration semiconductor wafer at each of the second plurality of locations across the surface of the calibration semiconductor wafer.

21. A semiconductor measurement system comprising:
an illumination source configured to generate an amount of illumination radiation incident on a semiconductor wafer at a measurement spot, wherein one or more critical dimension structures are fabricated on a surface of the semiconductor wafer at the measurement spot;
a detector configured to detect an amount of collected radiation from the semiconductor wafer in response to the incident amount of illumination radiation;
a specimen positioning system configured to position the semiconductor wafer with respect to the illumination source and the detector at a desired orientation about a first axis and a second axis, wherein the first axis and the second axis are aligned with the surface of the semiconductor wafer and the second axis is orthogonal to the first axis; and
a computing system configured to:
estimate the desired orientation of the semiconductor wafer with respect to the illumination source and the detector based on a location of the measurement spot on the semiconductor wafer and a local wafer orientation correction map; and
estimate a value of a parameter of interest characterizing the one or more structures based on the amount of collected radiation detected at the measurement spot after the semiconductor wafer is positioned about the first and second axes at the desired orientation.
